(19) United States
(12) Patent Application Publication
(10) Pub. No.: US 2011/0254161 A1
(43) Pub. Date: Oct. 20, 2011

(54) Integrated Circuit Package Having Under-Bump Metallization

(75) Inventor: Dyi-Chung Hu, Hsinchu County (TW)

(73) Assignee: Dyi Chung Hu, Hsinchu County (TW)

(21) Appl. No.: 13/041,702

(22) Filed: Mar. 7, 2011

(30) Foreign Application Priority Data
Apr. 15, 2010 (TW) 099206819

(51) Int. Cl. H01L 23/485

(52) U.S. Cl. 257/738; 257/E23.021

(57) ABSTRACT

An integrated circuit (IC) device uses a simple structure having X/Cu/Sn metal layers (X can be Ti or Ti/W etc.) without extra barrier layer. Thus, number of layers is reduced for a simple fabrication with good production and low cost.

### TECHNICAL FIELD OF THE DISCLOSURE

The present invention relates to an integrated circuit (IC) device; more particularly, relates to providing a metal layer having a simple X/Cu/Sn under-bump metallization (UBM) structure (X is Ti or Ti/W etc.) without extra barrier layer to reduce number of layers for a simple fabrication with good production and low cost.

### DESCRIPTION OF THE RELATED ART

In recent years, the integration of IC has been improved. For packaging IC, many packaging methods and package types are used, like wire bonding package (WB), tape automatic bonding (TAB), flip chip (FC), etc. On using a chip with a substrate having high-density I/O wires, inductance will be increased owing to long wire path. Besides, wire bonding results in high cost, low reliability and low production. Therefore, flip-chip technology (or controlled collapse chip connection, C4) was invented. In FIG. 3, an IC device 4 has a semiconductor device 40 which has a solder ball 50 on it. For soldering the solder ball 50 on the semiconductor device, a UBM structure 60 having a plurality of metal layers is formed on metal pads 441 of the semiconductor device 40, where, from the metal layer close to the semiconductor device 40 until the one close to the solder ball 50, these metal layers comprises an adhesion layer 61 formed on the metal pad 441, like a Ti layer; a conductor layer 62 made of a metal like Al, Cu, Au or Ag, etc.; a barrier layer 63 made of a metal like Ni, Cr or Pt, etc.; and a wettable layer 64 made of a metal like Au, Ag, Cu, Sn or other organic compound. Therein, the barrier layer 63 prevents the solder ball 50 from penetrating to react with the conductor layer 62; and, the wettable layer 64 provides wettability to the solder ball 50 and protects the metal layers. Through bonding the solder ball 50 on the UBM structure and providing adhesion between the solder ball 50 and the metal pads 441 of the semiconductor device 4, a solder is ball-dropped and pasted on the UBM stricture 60 and the solder ball 50 is formed on the solder through reflowing, where the UBM structure 60 is usually fabricated though sputtering, evaporating, or plating.

A flow for fabricating a UBM structure is shown in FIG. 4A to FIG. 4F. In FIG. 4A, a semiconductor device 40 having a plurality of aluminum pads 41 on a surface is provided at first. A passivation layer 42 is formed on the semiconductor device 40 with the aluminum pads 41 disclosed on the semiconductor device 40. A third dielectric layer 43 and a fourth dielectric layer 45 are formed on the passivation layer 42; and, a trace metal layer 44 is formed between the third dielectric layer 43 and the fourth dielectric layer 45 on the aluminum pads 41. The metal pads 441 of the trace metal layer 44 are disclosed in the fourth dielectric layer 45. In FIG. 4B, a Ti layer and a first copper layer 62a are formed on the fourth dielectric layer 45 and the metal pads 441 through sputtering, where the Ti layer is used as an adhesion layer 61. In FIG. 4C, a photoresist layer 65 is ball-dropped and pasted on the first copper layer 62a. In FIG. 4D, after exposing and developing, a second copper layer 62b, an Ni layer and an Au layer are sequentially formed on the first copper layer 62a through electroplating, where the first and the second copper layers 62a,62b are used as conductor layers 62; where the Ni layer is used as a barrier layer 63; and where the Au layer is used as a wettable layer 64. In FIG. 4E, the photoresist layer 65 is stripped off at last. In FIG. 4F, The adhesion layer 61 and the first copper layer 62a disclosed under the photoresist layer 65 are etched. Thus, an UBM structure 60 having Ti/Cu/Ni/Au layers is obtained.

However, on obtaining the flip chip, an intermetallic compound (IMC) layer will be formed, even with pinholes, through a eutectic reaction when the solder ball 50 is contacted with the Au-containing solder. Hence, cracks may happen between the solder ball 50 and the UBM layer 60, which may seriously affect reliability of the fabrication procedure.

Conclusively, the UBM structure 60 formed on the semiconductor device 40 needs many materials for fabrication through a lot of processes with increased cost. Moreover, quality and reliability of the solder material is reduced and so the final product has reduced wire connection quality with possibility of wire short and has a low production yield. Hence, the prior art does not fulfill all users' requests on actual use.

### SUMMARY OF THE DISCLOSURE

The main purpose of the present invention is to provide a metal layer having a simple X/Cu/Sn UBM structure (X is Ti or Ti/W etc.) without extra barrier layer to reduce number of layers for a simple fabrication with good production and low cost.

To achieve the above purpose, the present invention is an IC device using UBM, comprising a semiconductor device, a UBM layer and a solder bump, where the UBM layer comprises an adhesion layer, a conductor layer and a protection layer; the semiconductor device has a plurality of aluminum pads on a surface; where the semiconductor device is covered with a passivation layer on the surface; where the passivation layer has a plurality of first openings at a plurality of positions corresponding to the aluminum pads to partially disclose the aluminum pads; where a first dielectric layer is formed on the passivation layer and the first dielectric layer has a plurality of second openings to disclose at least a part of the aluminum pads; where a metal layer is formed on the first dielectric layer and the metal layer has a plurality of metal pads to be correspondingly electrically connected with the aluminum pads through the second openings; where a second dielectric layer is formed on the first dielectric layer and the metal layer; where the second dielectric layer has a plurality of third openings to correspondingly disclose the metal pads; where the UBM layer is formed on the metal pads disclosed in the third openings; where the UBM layer covers a part of the second dielectric layer around the third openings; where the adhesion layer is formed on the metal pads and the part of the second dielectric layer to be adhered with a substrate and the metal layer; where the conductor layer is formed on the adhesion layer; where the protection layer is formed on the conductor layer; and where the solder bump is formed on the protection layer. Accordingly, a novel IC device using UBM is obtained.

### BRIEF DESCRIPTIONS OF THE DRAWINGS

The present disclosure will be better understood from the following detailed description of the preferred embodiment according to the present disclosure, taken in conjunction with the accompanying drawings, in which

FIG. 1 is the structural view showing the preferred embodiment according to the present disclosure;

FIG. 2A is the view showing the semiconductor device;

FIG. 2B is the view showing the Ti/Cu layer on the semiconductor device;

FIG. 2C is the view showing the photoresist layer on the Ti/Cu layer;

FIG. 2D is the view showing the Ti/Cu layer partially etched;

FIG. 2E is the view showing the photoresist layer stripped on the partial Ti/Cu layer;

FIG. 2F is the view showing the immersion tin layer on the partial Ti/Cu layer;

FIG. 3 is the structural view of the prior art; and

FIG. 4A to FIG. 4F are the views of the flow for making the prior art.

### DESCRIPTION OF THE PREFERRED EMBODIMENT

The following description of the preferred embodiment is provided to understand the features and the structures of the present disclosure.

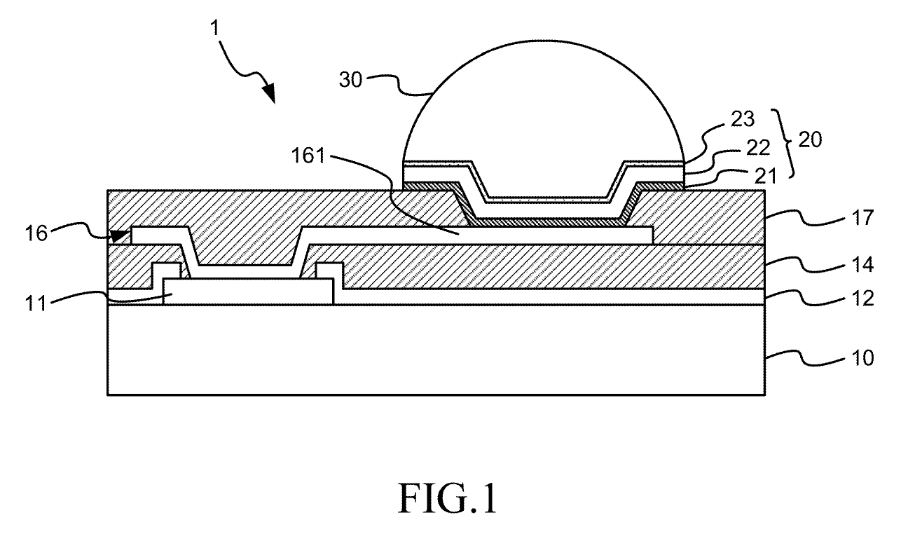

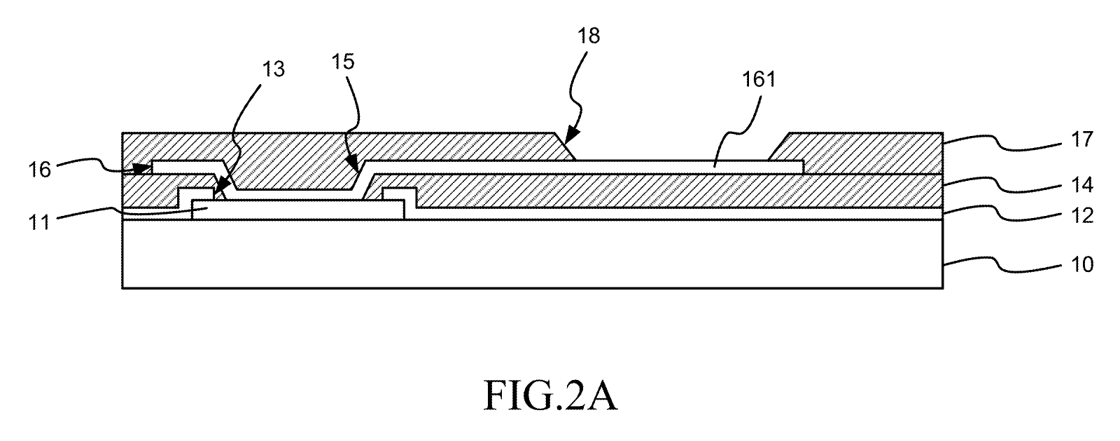

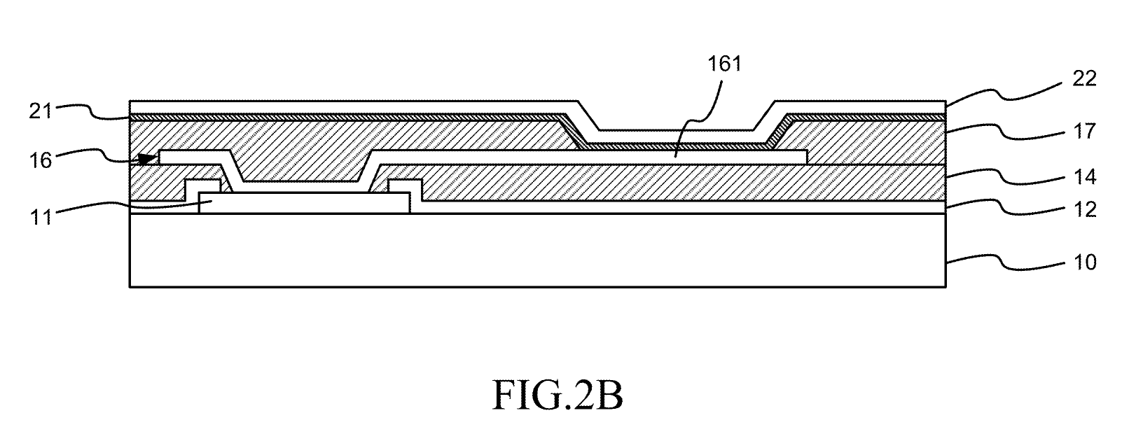

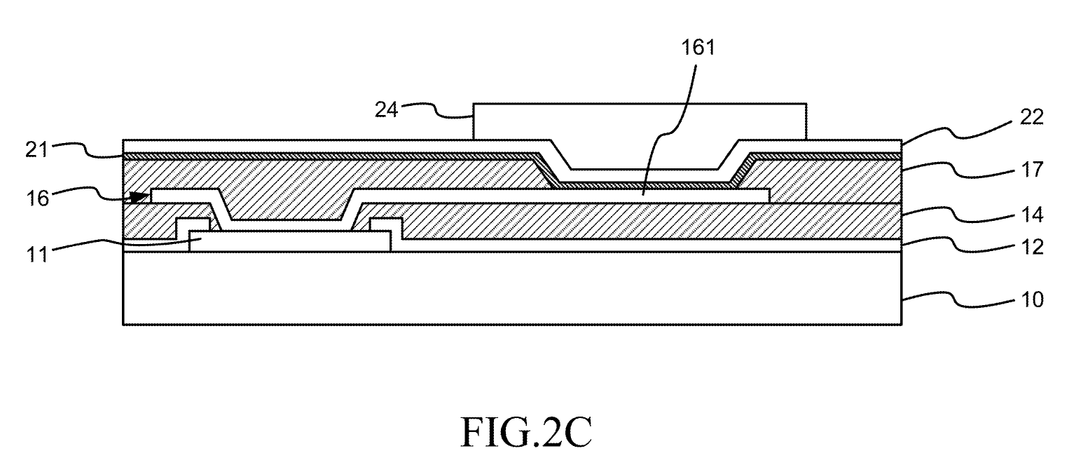

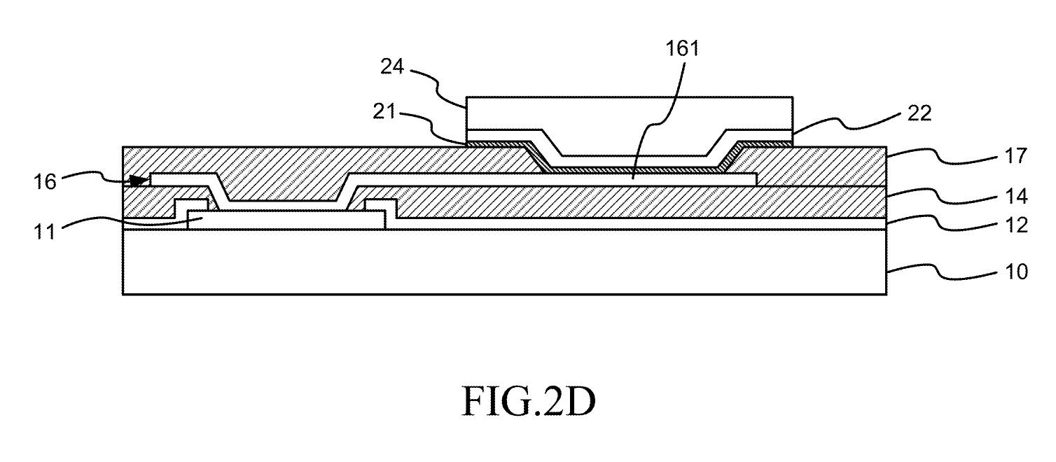

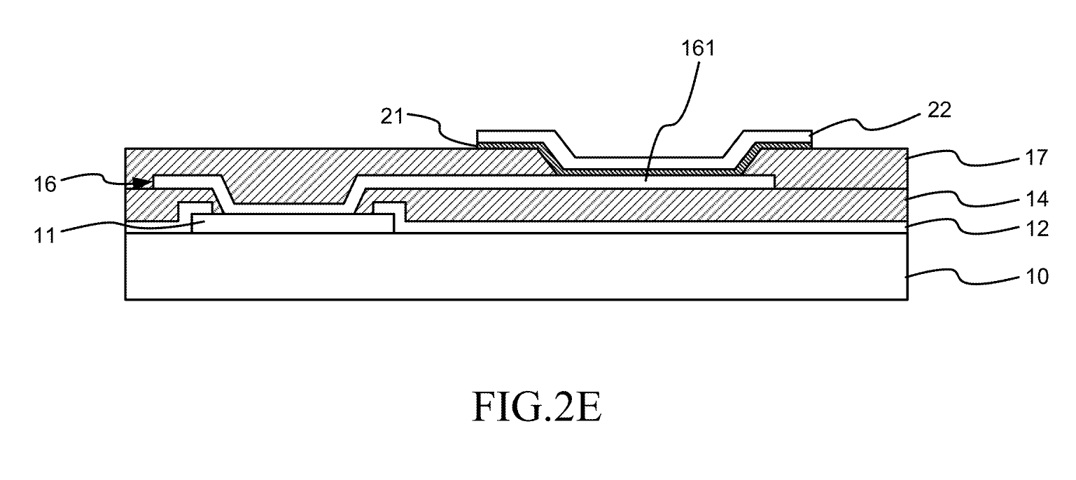

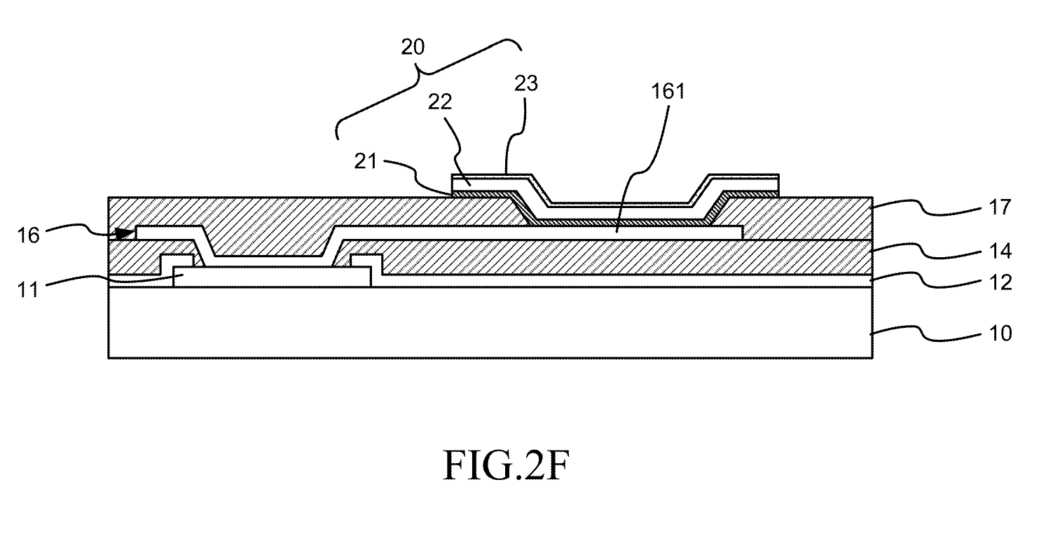

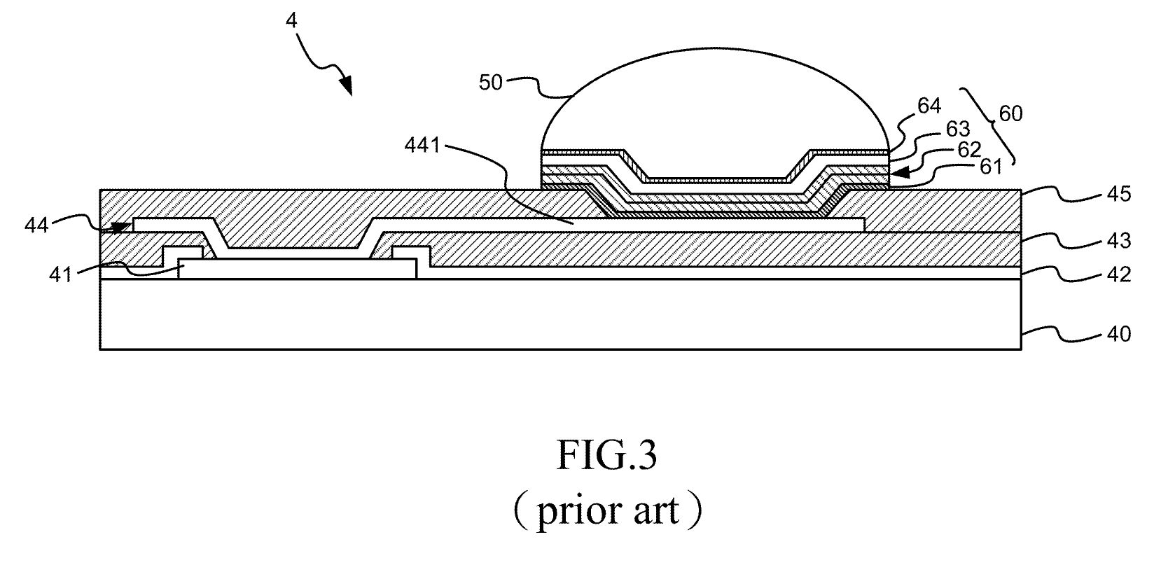

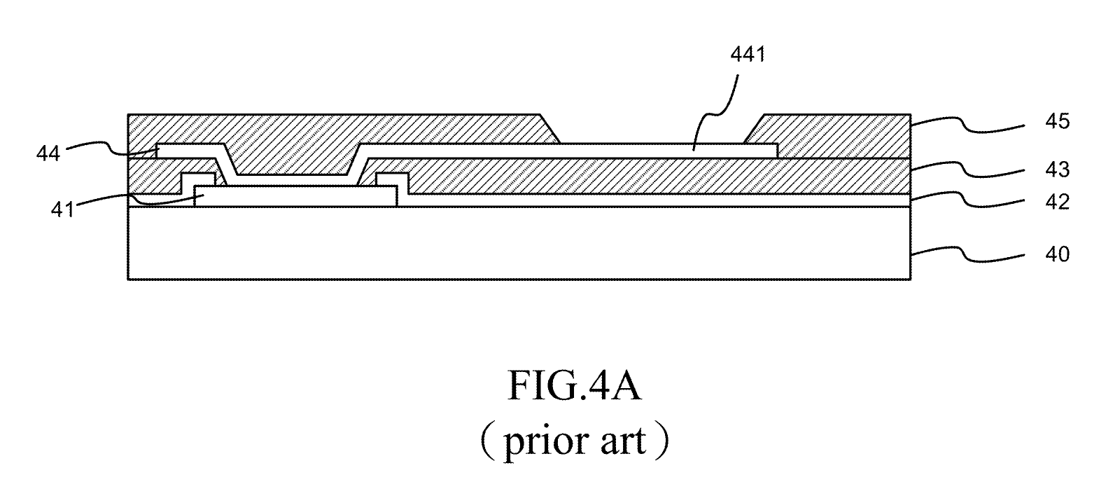

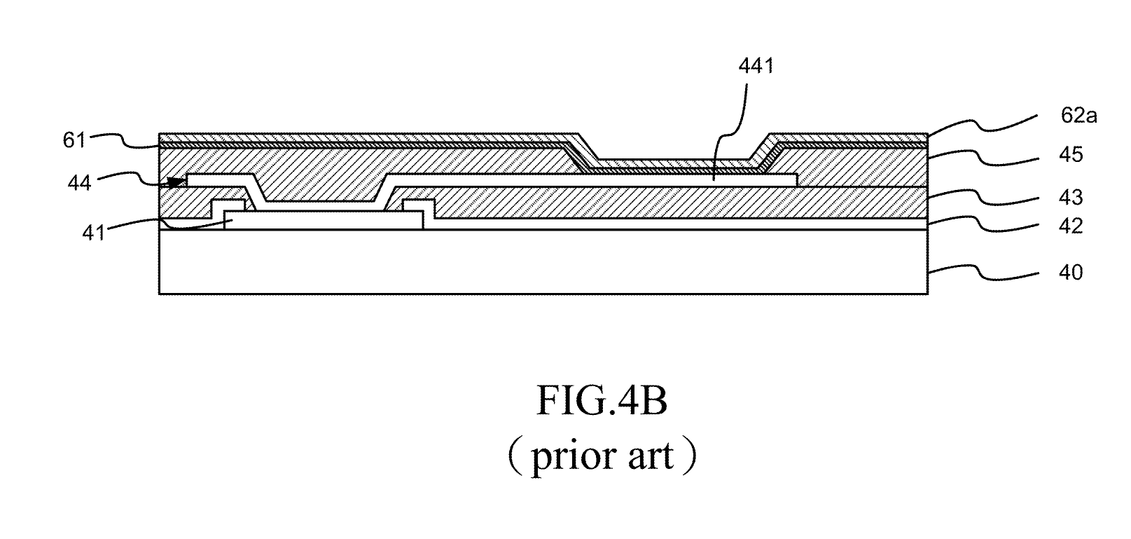

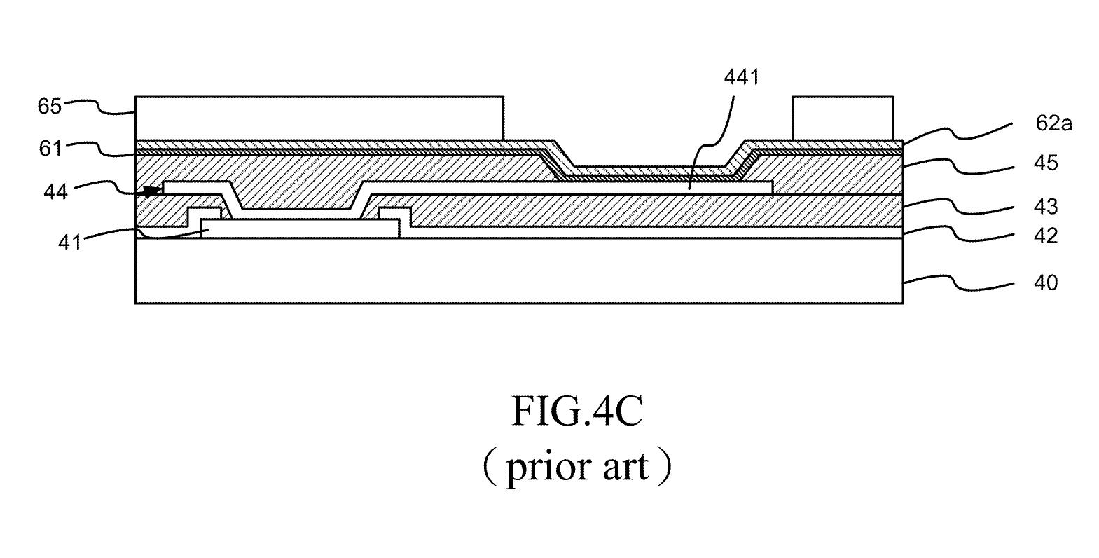

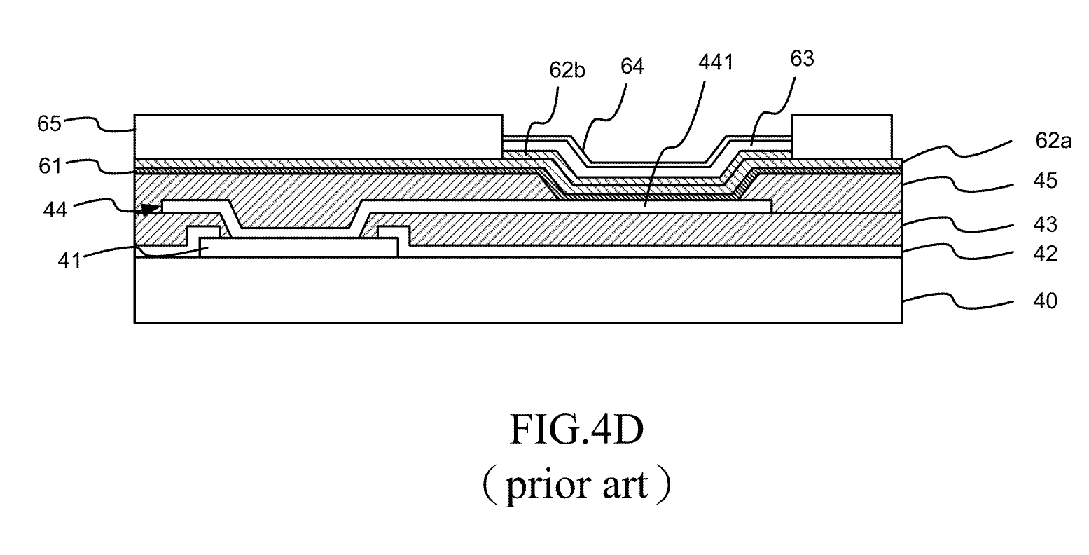

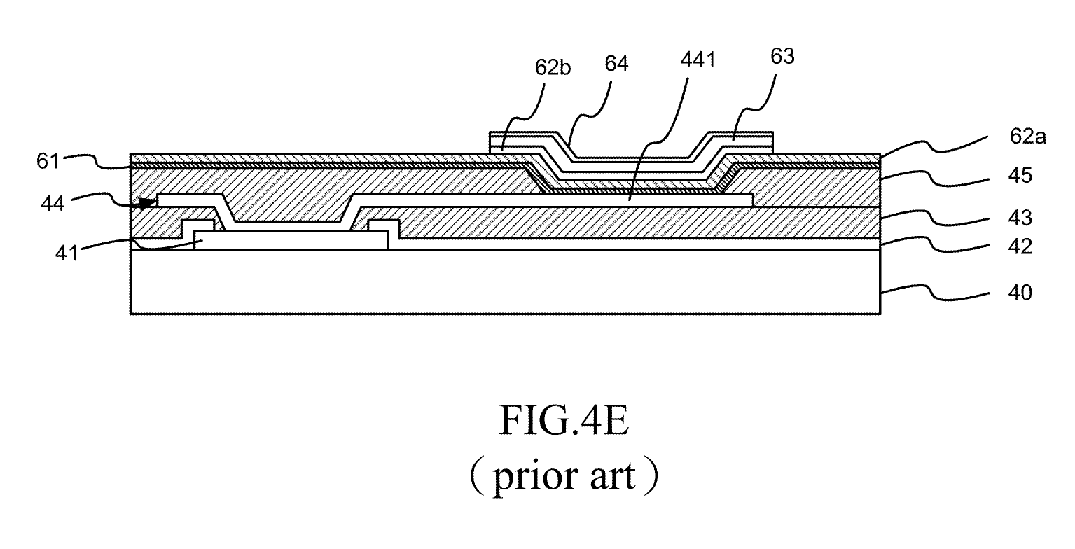

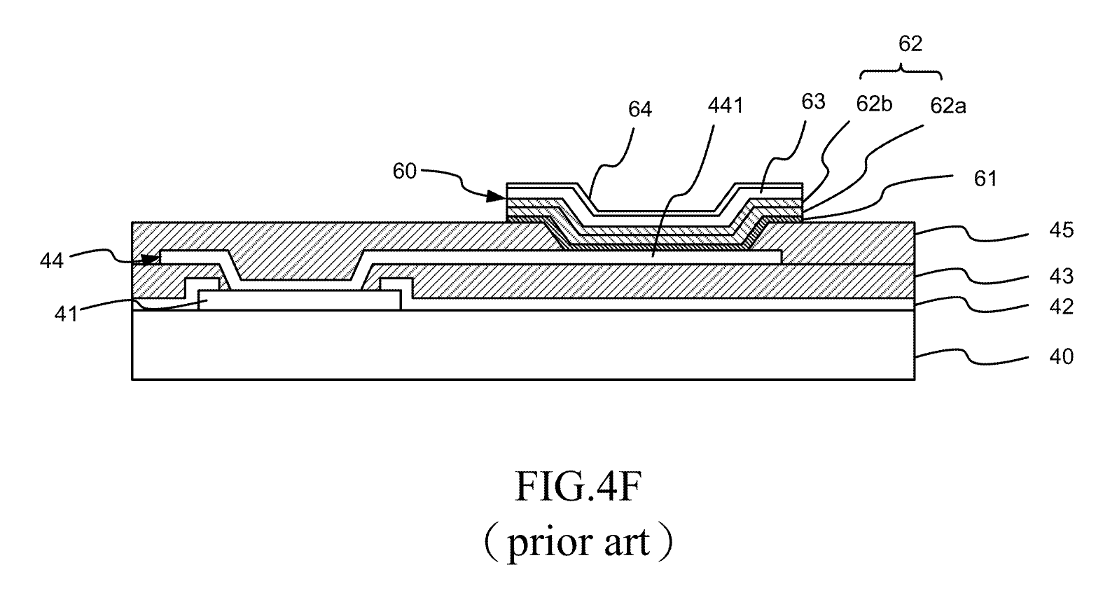

Please refer to FIG. 1 and FIG. 2A to FIG. 2F, which are a structural view showing a preferred embodiment according to the present disclosure; and views showing a semiconductor device; a Ti/Cu layer on the semiconductor device; a photoresist layer on the Ti/Cu layer; the Ti/Cu layer partially etched; the photoresist layer stripped on the partial Ti/Cu layer; and an immersion tin layer on the partial Ti/Cu layer. As shown in the figures, the present disclosure is an integrated circuit (IC) device 1 using under bump metallization (UBM), comprising a semiconductor device 10, a UBM layer 20 and a solder bump 30.

The semiconductor device 10 is a semiconductor chip, a semiconductor wafer, a semiconductor substrate or a semiconductor circuit board, where the semiconductor device 10 has a plurality of aluminum pads 11 on a surface and is covered with a passivation layer 12 on the surface; where the passivation layer 12 has a plurality of first openings 13 at a plurality of positions corresponding to the aluminum pads 11 to disclose the aluminum pads 11; where a first dielectric layer 14 is formed on the passivation layer 12 and has a plurality of second openings 15 to disclose at least a part of the aluminum pads 11; where a metal layer 16 of trace metal is formed on the first dielectric layer 14 and has a plurality of metal pads 161 to be correspondingly electrically connected with the aluminum pads 11 through the second openings 15 of the first dielectric layer 14; and where a second dielectric layer 17 is formed on the first dielectric layer 14 and the metal layer 16 and has a plurality of third openings 18 to correspondingly disclose the metal pads 161.

The UBM layer 20 is formed on the metal pads 161 disclosed in the third openings 18 of the semiconductor device 10 and covers a part of the second dielectric layer 17 around the third openings 18, where the UBM layer 20 comprises an adhesion layer 21, a conductor layer 22 and a protection layer 23; where the adhesion layer 21 is formed on the metal pads 161 and the part of the second dielectric layer 17 to be adhered with the metal layer 16; where the conductor layer 22 is formed on the adhesion layer 21; where the protection layer 23 is formed on the conductor layer 22 to provide a surface having solder-ability and to prevent the conductor layer 22 from oxidation; and where the UBM layer 20 has a X/Cu/Sn structure; and the X is a metal element like Ti, W, Cr, Ni, Pd or Pt, or is a metal alloy like Ti/W alloy or Cr/Ni alloy.

The solder bump 30 is formed on the protection layer 23 of the UBM layer 20.

Thus, a novel IC device 1 using UBM is obtained.

On using the present disclosure, a semiconductor chip is used for a semiconductor device 10; aluminum pads 11 are formed on the semiconductor device 10; and, a metal layer 16 made of Ti/Cu alloy is covered on the semiconductor device 10. Then, an adhesion layer 21, which has a thickness between 300 and 3000 Å, is formed on a surface of the second dielectric layer 17 through sputtering; then, a copper layer, which has a thickness between 2 and 20 μm, is formed as a conductor layer 22; and, then, a part of the copper layer is coated with a photoresist layer 24. Through exposing and developing, the disclosed Ti/Cu alloy of the photoresist layer 24 is etched. At last, the photoresist layer is stripped off and a protection layer 23 made of immersion tin is formed on the copper layer, where the protection layer 23 has a thickness between 0.1 and 1 μm. Thus, a UBM layer 20 having a Ti/Cu/Sn structure is formed. With the UBM layer 20, wetability of a solder bump 30 and the copper layer are increased for ensuring their contacts and copper is prevented from oxidation. Therein, the solder bump 30 is a solder ball; the protection layer 23 is made of electroless tin; and, the adhesion layer 21 is made of Ti, W, Cr, Ni, Pd or Pt, or is made of a metal alloy like Ti/W alloy or Cr/Ni alloy.

Hence, the present disclosure uses a UBM structure, which has X/Cu/Sn metal layers (where the X is Ti or Ti/W etc.) to reduce number of layers without extra barrier layer of expensive metal.

To sum up, the present disclosure is an IC device using UBM, where a structure having simple X/Cu/Sn metal layers without extra barrier layer is provided to reduce number of layers; and, the present disclosure is fabricated through a simple procedure with good production and low cost.

The preferred embodiment herein disclosed is not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. An integrated circuit (IC) device using under bump metallization (UBM), comprising:
a semiconductor device,
wherein said semiconductor device has a plurality of aluminum pads on a surface of said semiconductor device;
wherein said semiconductor device is covered with a passivation layer on said surface of said semiconductor device;
wherein said passivation layer has a plurality of first openings at a plurality of positions corresponding to said aluminum pads to partially disclose said aluminum pads;
wherein a first dielectric layer is obtained on said passivation layer and said first dielectric layer has a plurality of second openings to disclose at least a part of said aluminum pads;
wherein a metal layer of trace metal is obtained on said first dielectric layer and said metal layer has a plurality of metal pads to be correspondingly electrically connected with said aluminum pads through said second openings of said first dielectric layer;
wherein a second dielectric layer is obtained on said first dielectric layer and said metal layer; and
wherein said second dielectric layer has a plurality of third openings to correspondingly disclose said metal pads;
a UBM layer, comprising
an adhesion layer;
a conductor layer; and
a protection layer,
wherein said UBM layer is obtained on said metal pads disclosed in said third openings of said semiconductor device;
wherein said UBM layer covers a part of said second dielectric layer around said third openings;
wherein said adhesion layer is obtained on said metal pads and said part of said second dielectric layer to be adhered with a substrate and said metal layer;
wherein said conductor layer is obtained on said adhesion layer; and
wherein said protection layer is obtained on said conductor layer to provide a surface having solder-ability and to prevent said conductor layer from oxidation; and
a solder bump,
wherein said solder bump is obtained on said protection layer of said UBM layer.

2. The IC device according to claim 1,
wherein said semiconductor device is selected from a group consisting of a semiconductor chip, a semiconductor wafer, a semiconductor package substrate and a semiconductor circuit board.

3. The IC device according to claim 1,
wherein said adhesion layer is made of a material selected from a group consisting of at least one metal element and an alloy of said at least one metal element;
wherein said metal element is selected from a group consisting of Ti, W, Cr, Ni, Pd and Pt; and
wherein said alloy is selected from a group consisting of Ti/W alloy and Cr/Ni alloy.

4. The IC device according to claim 1,
wherein said conductor layer is a copper layer.

5. The IC device according to claim 1,
wherein said protection layer is made of immersion tin.

6. The IC device according to claim 1,
wherein said UBM layer has a structure of X/Cu/Sn; and
wherein said X is selected from a group consisting of at least one metal element and an alloy of said at least one metal element;
wherein said metal element is selected from a group consisting of Ti, W, Cr, Ni, Pd and Pt; and
wherein said alloy is selected from a group consisting of Ti/W alloy and Cr/Ni alloy.

7. The IC device according to claim 1,
wherein said solder bump is a solder ball.

8. The IC device according to claim 1,
wherein said adhesion layer has a thickness between 300 and 3000 Å;
wherein said conductor layer has a thickness between 2 and 20 μm; and
wherein said protection layer has a thickness between 0.1 and 1 μm.
